(19) United States
(12) Patent Application Publication
(10) Pub. No.: US 2025/0386534 A1
(43) Pub. Date: Dec. 18, 2025

(54) SHALLOW TRENCH ISOLATION (STI) FREE STRUCTURES FOR ADVANCED SEMICONDUCTOR TECHNOLOGIES

(71) Applicant: QUALCOMM Incorporated, San Diego, CA (US)

(72) Inventors: Yan SUN, San Diego, CA (US); Shreesh NARASIMHA, Charlotte, NC (US); Wei-Ta LEE, Hsinchu (TW)

(21) Appl. No.: 18/745,519

(22) Filed: Jun. 17, 2024

(51) Int. Cl. H01L 29/775; H01L 21/306; H01L 21/762; H01L 23/528; H01L 27/092; H01L 29/06; H01L 29/417; H01L 29/423; H01L 29/66; H01L 29/786

(52) U.S. Cl. CPC H10D 30/43; H01L 21/30625; H01L 21/76224; H01L 23/5286; H10D 30/014; H10D 30/031; H10D 30/6729; H10D 30/6735; H10D 30/6757; H10D 62/121; H10D 84/85

(57) ABSTRACT

A chip includes a first diffusion region extending in a first direction, the first diffusion region including first channels, and a second diffusion region extending in the first direction, the second diffusion region including second channels. The chip also includes a first gate extending in a second direction perpendicular to the first direction, wherein the first channels and the second channels pass through the first gate. The chip also includes a continuous backside interlayer dielectric (BS-ILD) under at least a portion of the first diffusion region, at least a portion of the second diffusion region, and a portion of the first gate between the first diffusion region and the second diffusion region.

### BACKGROUND

### Field

Aspects of the present disclosure relate generally to structures on a chip, and more particularly, to shallow trench isolation (STI) free structures on a chip.

### Background

A chip includes many active devices for performing various functions on the chip. The active devices may include transistors (e.g., gate-all-around field effect transistors (GAAFETs) and/or other types of transistors). The chip may also include shallow trench isolation (STI) for isolating active devices (e.g., transistors) on the chip.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a first diffusion region extending in a first direction, the first diffusion region including first channels, and a second diffusion region extending in the first direction, the second diffusion region including second channels. The chip also includes a first gate extending in a second direction perpendicular to the first direction, wherein the first channels and the second channels pass through the first gate. The chip also includes a continuous backside interlayer dielectric (BS-ILD) under at least a portion of the first diffusion region, at least a portion of the second diffusion region, and a portion of the first gate between the first diffusion region and the second diffusion region.

A second aspect relates to a chip. The chip includes a first diffusion region extending in a first direction, the first diffusion region including first channels, and a second diffusion region extending in the first direction, the second diffusion region including second channels. The chip also includes a first gate extending in a second direction perpendicular to the first direction, wherein the first channels and the second channels pass through the first gate. The chip also includes a continuous backside interlayer dielectric (BS-ILD) under the first channels, the second channels, and a portion of the first gate between the first channels and the second channels.

A third aspect relates to a method for processing a chip. The chip includes a first diffusion region, a second diffusion region, and a gate formed on a semiconductor substrate. The method includes removing most of the semiconductor substrate using chemical mechanical polishing (CMP), stopping the CMP when the CMP reaches a stop layer, etching away a portion of the semiconductor substrate that remains after the CMP, and forming a continuous backside interlayer dielectric (BS-ILD) under at least a portion of the first diffusion region, at least a portion of the second diffusion region, and a portion of the gate between the first diffusion region and the second diffusion region.

### BRIEF DESCRIPTION OF THE DRAWINGS

FIG. 1A shows a side view of an example of a chip including a transistor and multiple layers according to certain aspects of the present disclosure.

FIG. 1B shows a perspective view of the transistor implemented with a FinFET according to certain aspects of the present disclosure.

FIG. 1C shows a perspective view of the transistor implemented with a gate-all-around FET according to certain aspects of the present disclosure.

FIG. 1D shows a side view of the chip of FIG. 1A further including multiple backside layers according to certain aspects of the present disclosure.

FIG. 1E shows a side view of the chip of FIG. 1D further including a via disposed between a backside contact and a backside metal layer according to certain aspects of the present disclosure.

FIG. 2 shows a top view of an exemplary structure including diffusion regions and gates according to certain aspects of the present disclosure.

FIG. 3A shows a cross-sectional view of the structure of FIG. 2 including shallow trench isolation taken along a first cross-section line in FIG. 2 according to certain aspects of the present disclosure.

FIG. 3B shows a cross-sectional view of the structure of FIG. 2 including the shallow trench isolation taken along a second cross-section line in FIG. 2 according to certain aspects of the present disclosure.

FIG. 3C shows a cross-sectional view of the structure of FIG. 2 including the shallow trench isolation taken along a third cross-section line in FIG. 2 according to certain aspects of the present disclosure.

FIG. 4A shows an example of alternating layers of silicon and silicon germanium deposited on a substrate according to certain aspects of the present disclosure.

FIG. 4B shows an example in which the alternating layers of silicon and silicon germanium of FIG. 4A are etched to form a first vertical structure and a second vertical structure according to certain aspects of the present disclosure.

FIG. 4C show an example in which trenches are etched in the substrate according to certain aspects of the present disclosure.

FIG. 4D shows an example in which an isolation material is deposited on the chip according to certain aspects of the present disclosure.

FIG. 4E shows an example in which a portion of the isolation material above the first vertical structure and the second vertical structure is removed according to certain aspects of the present disclosure.

FIG. 4F shows an example in which portions of the isolation material are etched away around the first vertical structure and the second vertical structure according to certain aspects of the present disclosure.

FIG. 5A shows a cross-sectional view of the structure of FIG. 2 with no shallow trench isolation taken along the first cross-section line in FIG. 2 according to certain aspects of the present disclosure.

FIG. 5B shows a cross-sectional view of the structure of FIG. 2 with no shallow trench isolation taken along the second cross-section line in FIG. 2 according to certain aspects of the present disclosure.

FIG. 5C shows a cross-sectional view of the structure of FIG. 2 with no shallow trench isolation taken along the third cross-section line in FIG. 2 according to certain aspects of the present disclosure.

FIG. 6A shows an example of alternating layers of silicon and silicon germanium in which the bottom silicon germanium layer is thicker than the other silicon germanium layers according to certain aspects of the present disclosure.

FIG. 6B shows an example in which the alternating layers of silicon and silicon germanium of FIG. 6A are etched to form a first vertical structure and a second vertical structure according to certain aspects of the present disclosure.

FIG. 7 shows a top view of another exemplary structure including diffusion regions and gates according to certain aspects of the present disclosure.

FIG. 8A shows cross-sectional views of the structure of FIG. 7 before backside processing according to certain aspects of the present disclosure.

FIG. 8B shows the cross-sectional views of the structure of FIG. 7 after chemical mechanical polishing (CMP) of the substrate according to certain aspects of the present disclosure.

FIG. 8C shows the cross-sectional views of the structure of FIG. 7 after a remaining portion of the substrate is etched away and after formation of a backside interlayer dielectric (BS-ILD) according to certain aspects of the present disclosure.

FIG. 8D shows the cross-sectional views of the structure of FIG. 7 after sacrificial material is removed from a backside contact creating a backside trench according to certain aspects of the present disclosure.

FIG. 8E shows the cross-sectional views of the structure of FIG. 7 after the backside trench is filled with contact material according to certain aspects of the present disclosure.

FIG. 9 is a flowchart illustrating a method for processing a chip according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

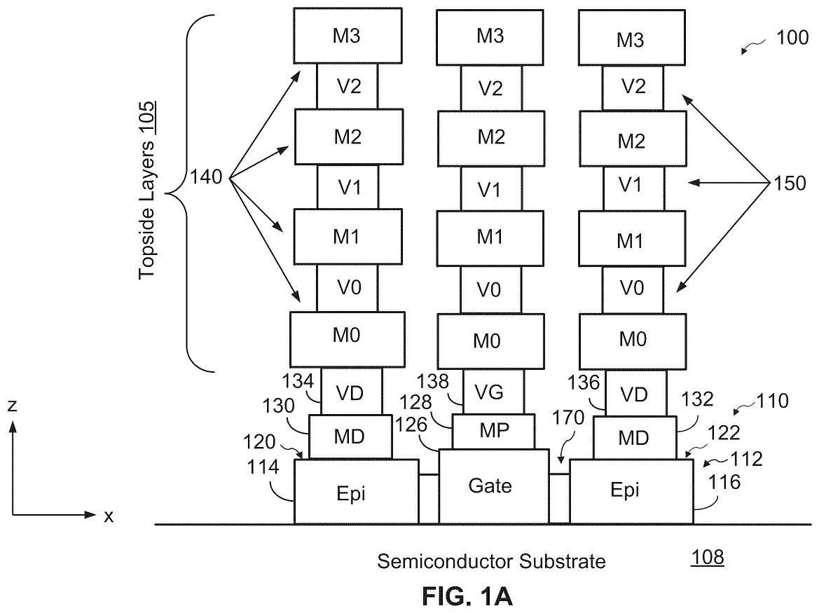

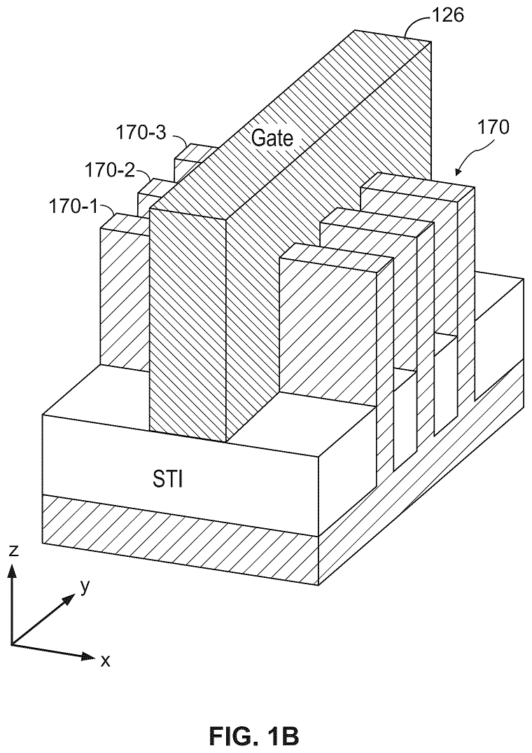

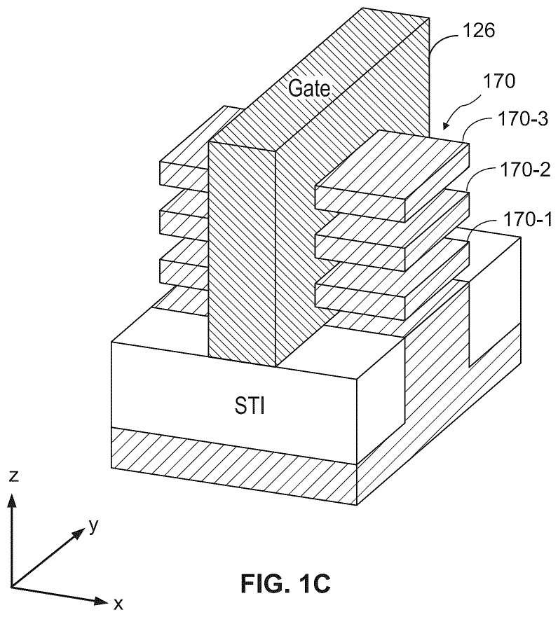

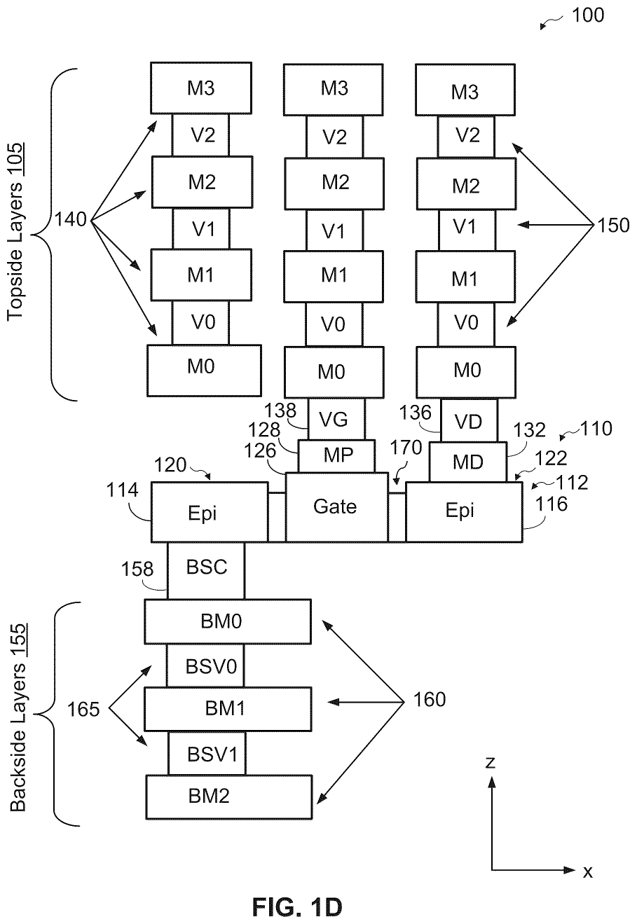

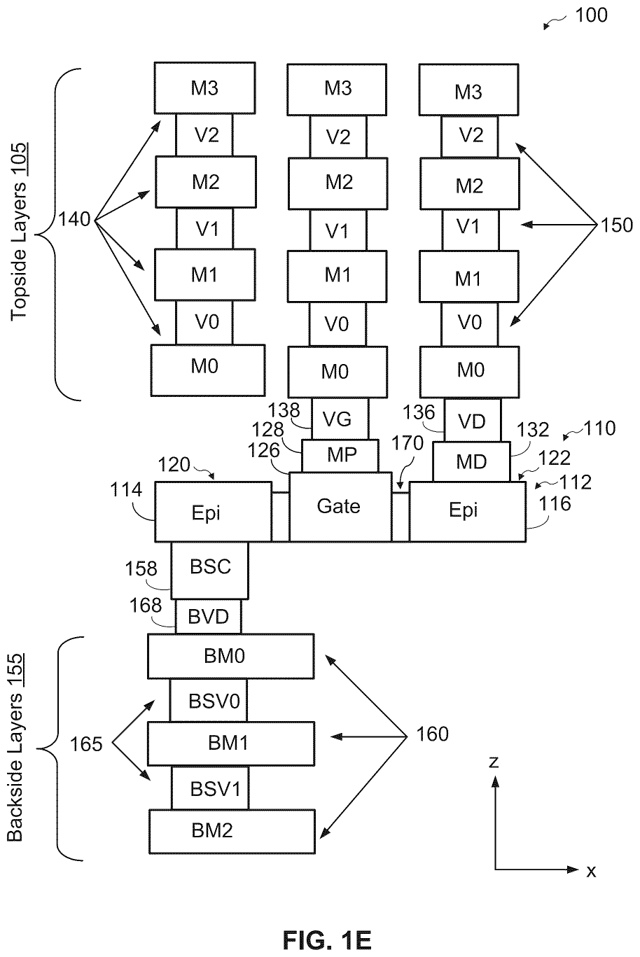

FIG. 1A shows a side view of an example of a chip 100 (e.g., a die) including a transistor 110 and multiple topside layers 105 (also referred to as frontside layers) according to certain aspects. Although one transistor 110 is shown in FIG. 1A for simplicity, it is to be appreciated that the chip 100 includes many transistors. As discussed further below, the transistor 110 may be implemented using a gate-all-around field effect transistor (FET) process, a fin field-effect transistor (FinFET) process, or another type of process. The topside layers 105 are above the transistor 110 in the z direction shown in FIG. 1A. The transistor 110 and the topside layers 105 may be formed on a semiconductor substrate 108 (e.g., silicon substrate).

In the example shown in FIG. 1A, the transistor 110 includes a diffusion region 112 and a gate 126 on the diffusion region 112. The diffusion region 112 may also be referred to as an oxide diffusion region, an active region, active diffusion, active (RX), or another term. The gate 126 may be formed on the diffusion region 112, and may include a gate metal (e.g., a high-k metal gate (HKMG)), polysilicon, and/or another gate material. The diffusion region 112 includes one or more channels 170 extending in the x direction in FIG. 1A, where the x direction is perpendicular to the z direction. As used herein, a “channel” is a structure that conducts current between a source and a drain of a transistor.

For the example of a FinFET process, the gate 126 may surround each of the one or more channels 170 on three sides. In this regard, FIG. 1B shows a perspective view in which the one or more channels 170 include channels 170-1, 170-2, and 170-3 where each of the channels 170-1, 170-2, and 170-3 is surrounded on three sides by the gate 126. In this example, each of the channels 170-1, 170-2, and 170-3 is orientated vertically, and the channels 170-1, 170-2, and 170-3 are spaced apart from one another in the y direction. The channels for a FinFET process may also be referred to as fins. In certain aspects, the chip 100 may include shallow trench isolation (STI) to reduce leakage between active devices on the chip 100. However, as discussed further below, the STI may be omitted to reduce process complexity and reduce process cost.

For the example of a gate-all-around FET process, the gate 126 may surround each of the one or more channels 170 (also referred as ribbons) on four sides. In this regard, FIG. 1C shows a perspective view in which the one or more channels 170 include channels 170-1, 170-2, and 170-3 where each of the channels 170-1, 170-2, and 170-3 is surrounded on four sides by the gate 126. Each of the channels 170-1, 170-2, and 170-3 may include a nanosheet, a nanowire, or the like. In this example, the channels 170-1, 170-2, and 170-3 are stacked vertically and are spaced apart from one another in the z direction. However, it is to be appreciated that the present disclosure is not limited to this example.

Returning to FIG. 1A, the transistor 110 may include a first epitaxial (epi) layer 114 and a second epi layer 116 in which the gate 126 is disposed between the first epi layer 114 and the second epi layer 116. The first epi layer 114 is coupled to the one or more channels 170 on one side of the gate 126 to provide a first source/drain 120. The second epi layer 116 is coupled to the one or more channels 170 on the other side of the gate 126 to provide a second source/drain 122. An epi layer may also be referred to as simply epi or another term. As used herein, the term “source/drain” means a source, a drain, or both a source and a drain.

As shown in FIG. 1A, the first epi layer 114 and the second epi layer 116 are located on opposite sides of the gate 126. Each of the first epi layer 114 and the second epi layer 116 may include epitaxially grown or deposited silicon, a silicon-based material (e.g., silicon-germanium), or any combination thereof. In this example, the gate 126 controls the conductivity between the first source/drain 120 and the second source/drain 122 based on a voltage applied to the gate 126. The transistor 110 may include a thin spacer (not shown in FIG. 1A) between the gate 126 and each of the first epi layer 114 and the second epi layer 116. A spacer may also be referred to as a sidewall spacer or another term.

In this example, the chip 100 includes a first contact 130 formed on a top surface of the first source/drain 120 and a second contact 132 formed on a top surface of the second source/drain 122. A top surface may also be referred to as a frontside surface. The contacts 130 and 132 may be formed (i.e., patterned) from a contact layer using, for example, lithographic and etching processes. Each of the contacts 130 and 132 may be referred to as a metal-diffusion (MD) contact, contact active (CA), or another term. Each of the contacts 130 and 132 may include cobalt (Co), tungsten (W), molybdenum (Mo), another conductive material, or any combination thereof.

The chip 100 may also include a gate contact 128 formed on the gate 126. The gate contact 128 may be referred to as a metal-poly (MP) contact or another term. The gate contact 128 may be omitted in some implementations.

In this example, the topside layers 105 include metal layers 140 (also referred to as a metal stack). The metal layers 140 may be patterned (e.g., using lithography and etching) to provide signal routing for the transistor 110 and other transistors (not shown in FIG. 1A) integrated on the chip 100. The metal layers 140 may also be patterned to form a power distribution network including supply rails for distributing power to the transistor 110 and other transistors integrated on the chip 100. A supply rail may also be referred to as a power rail or another term.

In the example in FIG. 1A, the bottom-most metal layer among the metal layers 140 is referred to as metal layer M0. The metal layer immediately above metal layer M0 is referred to as metal layer M1, the metal layer immediately above metal layer M1 is referred to as metal layer M2, the metal layer immediately above metal layer M2 is referred to as metal layer M3, and so forth. Although four metal layers 140 (i.e., M0 to M3) are shown in FIG. 1A for ease of illustration, it is to be appreciated that the topside layers 105 may include additional metal layers above metal layer M3. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M in other examples. Accordingly, it is to be appreciated that the metal layers are not limited to the exemplary designations used in FIG. 1A.

The topside layers 105 also includes vias 150 that provide coupling between the metal layers 140. The vias 150 include vias V0, vias V1, and vias V3. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip 100 also includes a via 136 (labeled “VG”) disposed between the gate contact 128 and metal layer M0, in which the via 136 couples the gate contact 128 (and hence the gate 126) to metal layer M0. For implementations where the gate contact 128 is omitted, the via 136 may be disposed between the gate 126 and metal layer M0 without an intervening gate contact. In this example, the chip 100 also includes a via 134 (labeled “VD”) disposed between the contact 130 and metal layer M0, in which the via 134 couples the contact 130 to metal layer M0. The chip 100 also includes a via 136 (labeled “VD”) disposed between the contact 132 and metal layer M0, in which the via 136 couples the contact 132 to metal layer M0.

In certain aspects, the chip 100 may include backside layers to facilitate backside routing. In these aspects, most or all of the semiconductor substrate 108 is removed to form backside layers under the transistors (e.g., transistor 110) on the chip 100. As used here, “most” of the semiconductor substrate 108 means at least 90 percent of the semiconductor substrate 108. For example, after formation of the transistors and the topside layers 105, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off (e.g., using chemical mechanical polishing (CMP)). Backside layers may then be formed under the transistors on the chip 100.

In this regard, FIG. 1D shows an example of backside layers 155 formed under the transistor 110. In this example, the backside layers 155 include backside metal layers 160. The backside metal layers 160 may be patterned (e.g., using lithography and etching) to form a backside power distribution network and/or backside signal routing. The backside power distribution network may include supply rails for distributing power to the transistor 110 and other transistors on the chip 100.

In the example in FIG. 1D, the top-most backside metal layer among the backside metal layers 160 is referred to as backside metal layer BM0. The backside metal layer immediately below backside metal layer BM0 is referred to as backside metal layer BM1, the backside metal layer immediately below backside metal layer BM1 is referred to as backside metal layer BM2, and so forth. Although three backside metal layers 160 (i.e., BM0 to BM2) are shown in FIG. 1D for ease of illustration, it is to be appreciated that the backside layers 155 may include additional metal layers below backside metal layer BM2.

In the example in FIG. 1D, the chip 100 includes a backside contact 158 formed on a bottom surface (i.e., backside surface) of the first source/drain 120. The backside contact 158 may be formed (i.e., patterned) from a backside contact layer (labeled “BSC”) using, for example, lithographic and etching processes. The backside contact 158 is used to couple the first source/drain 120 to backside metal layer BM0. In some implementations, the backside contact 158 may directly contact backside metal layer BM0, as shown in the example in FIG. 1D. In other implementations, the backside contact 158 may be coupled to backside metal layer BM0 through an intervening via. In this regard, FIG. 1E shows an example in which the chip 100 includes a backside via 168 (labeled “BVD”) disposed between the backside contact 158 and backside metal layer BM0. In this example, the backside via 168 provides a space between the backside contact 158 and backside metal layer BM0 in the z direction.

In the examples in FIG. 1D and FIG. 1E, the backside layers 155 include vias 165 that provide coupling between the backside metal layers 160. In this example, the vias 165 include a via BSV0 that provides coupling between backside metal layer BM0 and backside metal layer BM1, and a via BSV1 that provides coupling between backside metal layer BM1 and backside metal layer BM2.

In certain aspects, the topside metal layers 140 are patterned (e.g., using lithography and etching) to provide signal routing for the transistor 110 and other transistors (not shown in FIG. 1A) integrated on the chip 100, and the backside metal layers 160 are patterned to form a power distribution network including supply rails for distributing power to the transistor 110 and the other transistors integrated on the chip 100. Moving the power distribution network to the backside layers 155 helps reduce routing congestion compared with the case in which the topside layers 105 are used for both signal routing and power distribution. It is to be appreciated that, in some implementations, both the topside metal layers 140 and the backside metal layers 160 may be used for signal routing. In general, the present disclosure is not limited to a particular allocation of power routing and signal routing between the topside layers 105 and the backside layers 155.

Although one gate 126 is shown in FIGS. 1A to 1E, it is to be appreciated that the transistor 110 may include multiple gates arranged in parallel and coupled to one another (e.g., through metal layer M0 or another metal layer). A transistor with multiple gates may be referred to as a multi-gate transistor, a multi-finger transistor, or another term.

Transistors on the chip 100 may be organized into cells. Each cell may include one or more transistors that are arranged to implement a circuit (e.g., an inverter, a driver, a logic gate, combinational logic, a latch, a flip-flop, a bit cell, or another type of circuit). The layout of each cell may be specified (i.e., defined) in a standard cell library, which may be stored in a memory. The standard cell library may specify (i.e., define) the layout of each one of various cells that can be placed (i.e., laid out) on the chip 100 for a particular process. The chip 100 may include multiple instances of a particular cell defined in the standard cell library. The layout of each cell defined in the standard cell library may include the layout of gates, diffusion regions, and contacts in the cell. A cell that is defined in a standard cell library may also be referred to as a standard cell.

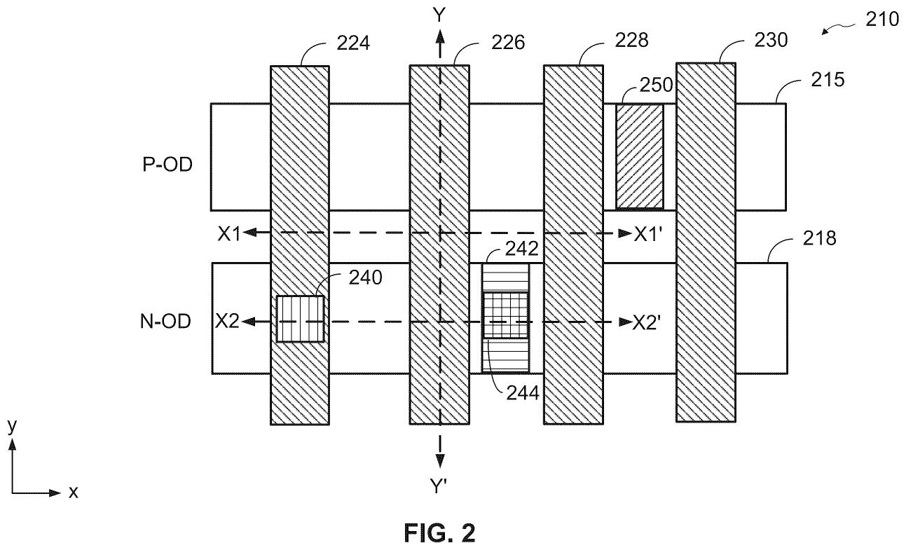

FIG. 2 shows a top view of an exemplary structure 210 on the chip 100 according to certain aspects. The structure 210 may be in a standard cell in some implementations. In this example, the structure 210 include a first diffusion region 215 and a second diffusion region 218 extending in the x direction. The first diffusion region 215 may be a p-type diffusion region (labeled “P-OD”) and the second diffusion region 218 may be an n-type diffusion region (labeled “N-OD”). For ease of illustration, the diffusion regions 215 and 218 are shown as rectangles in FIG. 2.

In this example, the structure 210 also includes gates 224, 226, 228, and 230 extending in the y direction. The gates 224, 226, 228, and 230 may be spaced apart in the x direction by a uniform pitch, as shown in the example in FIG. 2. Each of the gates 224, 226, 228, and 230 may include a gate metal (e.g., a high-k metal gate (HKMG)), polysilicon, and/or another gate material. It is to be appreciated that the structure 210 is not limited to the number of gates shown in the example in FIG. 2, and that the structure 210 may include a smaller number of gates or a larger number of gates.

In this example, the first diffusion region 215 may include one or more channels extending in the x direction (e.g., the one or more channels 170) and one or more epi layers (e.g., the epi layers 114 and 116). Also, the second diffusion region 218 may include one or more channels extending in the x direction (e.g., the one or more channels 170) and one or more epi layers (e.g., the epi layers 114 and 116). Each channel may include a nanosheet, a nanowire, or another type of channel.

In the example in FIG. 2, the structure 210 includes a gate via 240 (e.g., VG via in FIGS. 1A, 1D, and 1E) disposed on the gate 224 for coupling the gate 224 to signal routing in metal layer M0 (not shown in FIG. 2). The structure 210 also includes a source/drain contact 242 (e.g., MD contact in FIGS. 1A, 1D, and 1E) disposed on a top surface of the second diffusion region 218, and a via 244 (e.g., VD via in FIGS. 1A, 1D, and 1E) disposed on the source/drain contact 242. The source/drain contact 242 and the via 244 may couple the second diffusion region 218 to signal routing in metal layer M0. In this example, the structure 210 further includes a backside contact 250 (e.g., BSC in FIGS. 1D and 1E) coupled to a back surface of the first diffusion region 215. The backside contact 250 may be used, for example, to couple the first diffusion region 215 to a supply rail in backside metal layer BMO (not shown in FIG. 2).

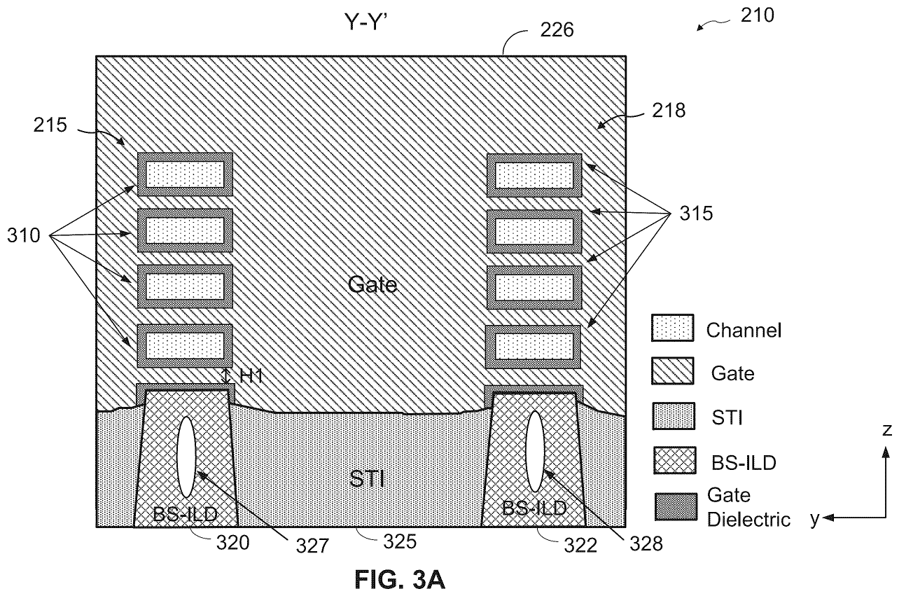

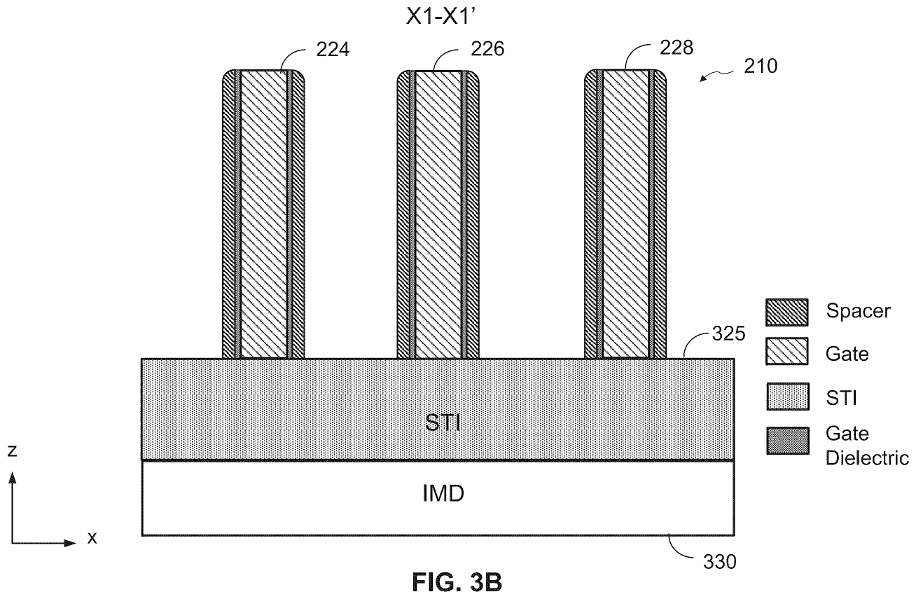

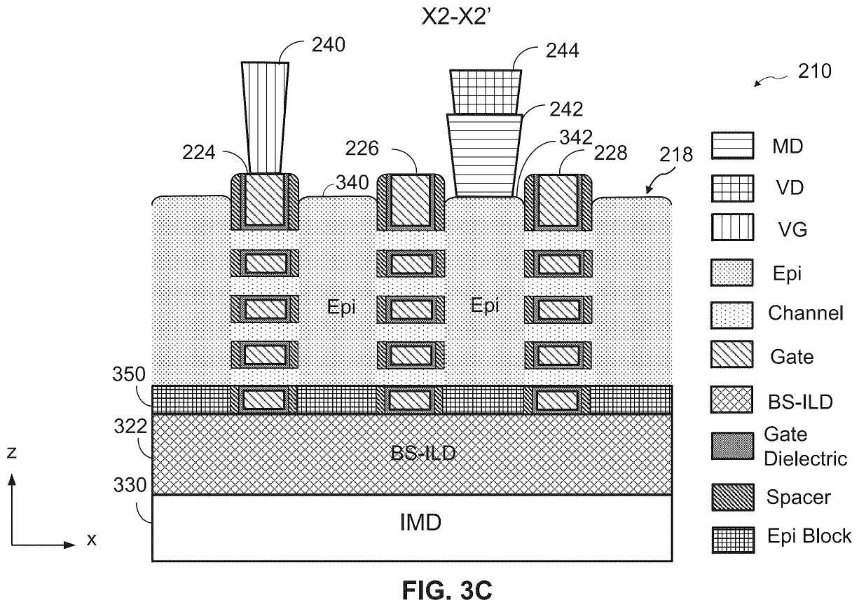

FIG. 3A shows a cross-sectional view of the structure 210 taken along the cross-section line Y-Y′ in FIG. 2. In this example, the structure 210 includes shallow trench isolation (STI), as discussed further below.

In this example, the first diffusion region 215 includes first channels 310 passing through the gate 226 and the second diffusion region 218 includes second channels 315 passing through the gate 226. Each of the first channels 310 and each of the second channels 315 may be surrounded by a thin gate dielectric. In the example shown in 3A, the channels 310 and 315 are formed using a gate-all-around FET process in which each of the channels 310 and 315 is surrounded on four sides by the gate 226. However, it is to be appreciated that the present disclosure is not limited to this example.

In this example, the structure 210 includes a first pillar 320 under the first diffusion region 215 and a second pillar 322 under the second diffusion region 218. Each of the pillars 320 and 322 includes a backside interlayer dielectric (BS-ILD).

In this example, the structure 210 also includes a shallow trench isolation (STI) region 325 between the first pillar 320 and the second pillar 322 in the y direction. The STI region 325 is used to reduce leakage between the active devices corresponding to the first diffusion region 215 and the second diffusion region 218.

In the example shown in FIG. 3A, the first pillar 320 includes a seam 327 (i.e., void) in the BS-ILD and the second pillar 322 includes a seam 328 (i.e., void) in the BS-ILD. The seams 327 and 328 may be a byproduct of the process used to form the pillars 320 and 322 in which narrow trenches are etched in the substrate and then back filled with the BS-ILD to form the pillars 320 and 322.

FIG. 3B shows a cross-sectional view of the structure 210 taken along the cross-section line X1-X1′ in FIG. 2, which runs in the x direction between the first diffusion region 215 and the second diffusion region 218.

In this example, the STI region 325 extends in the x direction under the gates 224, 226, and 228 and between the first diffusion region 215 and the second diffusion region 218 (shown in FIG. 2). In this example, the chip 100 includes an inter-metal dielectric (IMD) 330 under the STI region 325. The IMD 330 may be used, for example, to isolate structures (e.g., supply rails and ground rails) formed in one or more of the backside metal layers (e.g., backside metal layers 160 in FIGS. 1D and 1E). In some implementations, the chip may include a BS-ILD between the STI region 325 and the IMD 330. In the example shown in FIG. 3B, the structure 210 may also include thin spacers on opposite side walls of each of the gates 224, 226, and 228

FIG. 3C shows a cross-sectional view of the structure 210 taken along the cross-section line X2-X2′ in FIG. 2, which runs in the x direction and intersects the second diffusion region 218. In this example, the second diffusion region 218 includes a first epi layer 340 between the gates 224 and 226 and a second epi layer 342 between the gates 226 and 228. An epi block layer 350 may be disposed below the epi layers 340 and 342 (e.g., to block the epi layers 340 and 342 from growing into the substrate 108 during frontside processing).

In the example in FIG. 3C, the second pillar 322 (which includes the BS-ILD) extends in the x direction under the second diffusion region 218. Also, in this example, the gate via 240 is disposed on the gate 224 (e.g., to couple the gate 224 to signal routing in metal layer M0) and the source/drain contact 242 is disposed on the top surface of the second epi layer 342 (e.g., to couple the second epi layer 342 to signal routing in metal layer M0).

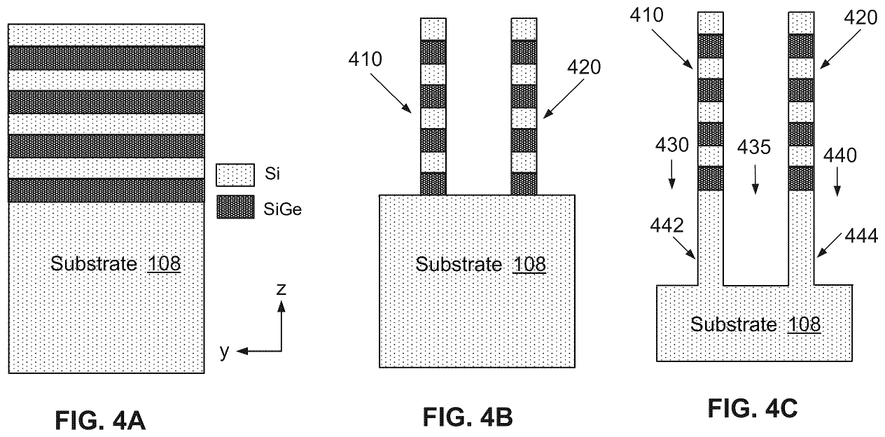

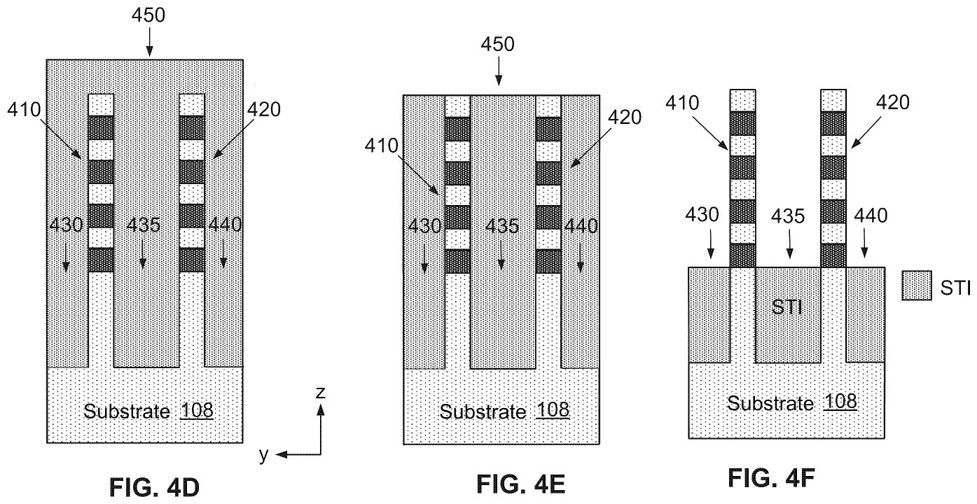

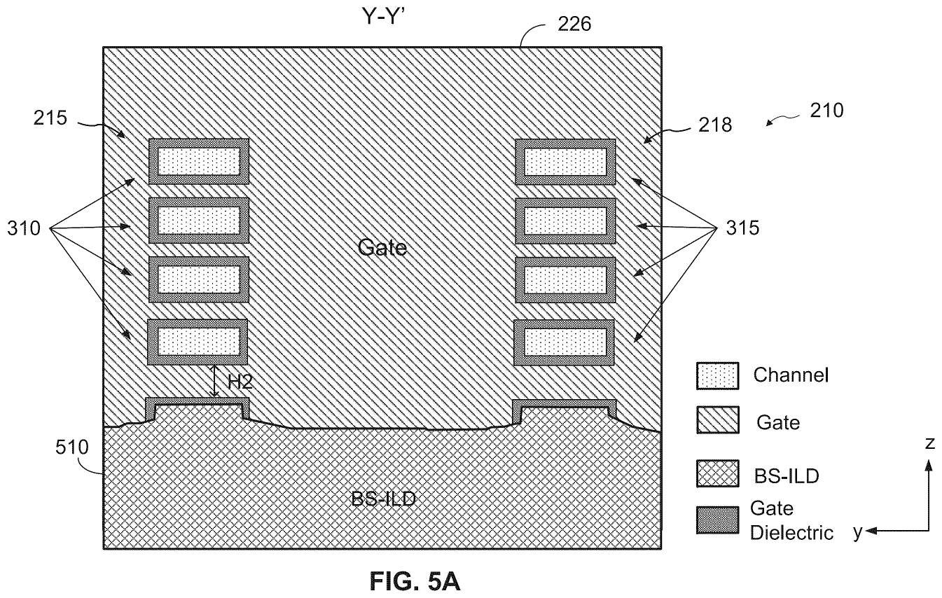

Thus, in the example shown in FIGS. 3A to 3C, the structure 210 includes STI for device isolation. However, forming the STI adds additional process complexity and process cost. This may be shown with reference to FIGS. 4A to 4F, which illustrate process steps including process steps for forming the STI. FIGS. 4A to 4F show cross-sectional views that intersect two adjacent diffusion regions in the y direction (e.g., the first diffusion region 215 and the second diffusion region 218).

In FIG. 4A, alternating layers of silicon and silicon germanium are deposited on the substrate 108 (e.g., silicon substrate). The layers of silicon are used to form channels (e.g., the channels 310 and 315). The layers of silicon germanium are sacrificial layers that are removed in a later process to form the portions of the gate (e.g., the gate 226) between the channels.

In FIG. 4B, the alternating layers of silicon and silicon germanium are etched to form a first vertical structure 410 and a second vertical structure 420. Each of the vertical structures 410 and 420 includes alternating layers of silicon and silicon germanium. In one example, the silicon layers in the first vertical structure 410 may be used to form the first channels 310 and the silicon layers in the second vertical structure 420 may be used to form the second channels 315.

In FIG. 4C, trenches 430, 435, and 440 are etched in the substrate 108. In this example, a first silicon pillar 442 is formed between the trenches 430 and 435 and a second silicon pillar 444 is formed between the trenches 435 and 440. The first silicon pillar 442 is under the first vertical structure 410 and the second silicon pillar 444 is under the second vertical structure 420.

In FIG. 4D, an isolation material 450 is deposited on the chip 100. In this example, the isolation material 450 fills the trenches 430, 435, and 440 and the spaces around the vertical structures 410 and 420.

In FIG. 4E, the excess portion of the isolation material 450 above the vertical structures 410 and 420 is removed (e.g., in a planarization process).

In FIG. 4F, the isolation material 450 is etched away around the vertical structures 410 and 420 including etched away from the space between the vertical structures 410 and 420. This leaves the isolation material 450 filling the trenches 430, 435 and 440, which form the STI.

In the example shown in FIGS. 4A to 4F, the formation of the STI includes the process steps shown in FIGS. 4C to 4F. The formation of the STI may include additional process steps not shown in FIGS. 4C to 4F including, for example, corner rounding, annealing, liner deposition, cleaning, etc. Thus, the process steps for the STI add additional process complexity and process cost. To address this, aspects of the present disclosure provide STI free structures that eliminate the need for the STI process steps, thereby reducing process complexity and process cost, as discussed further below.

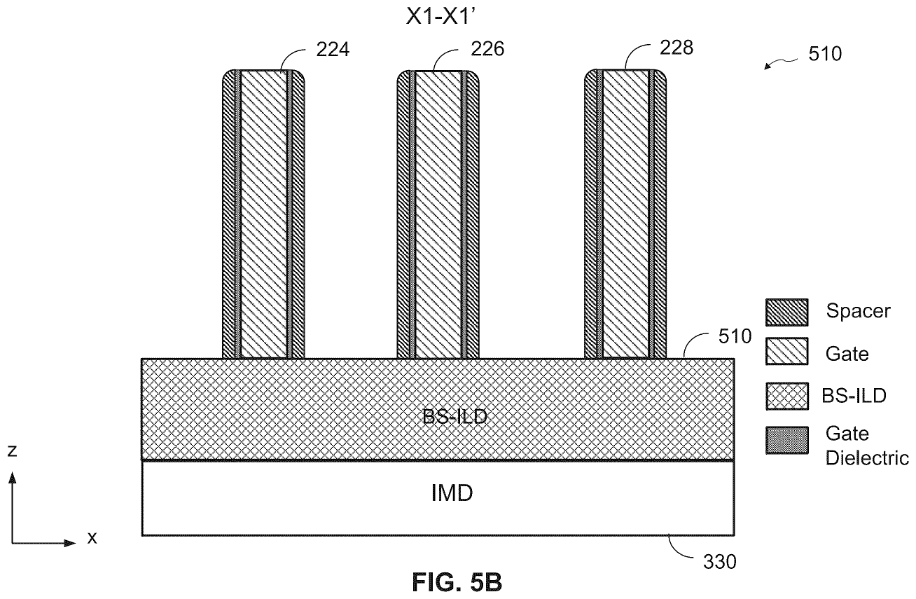

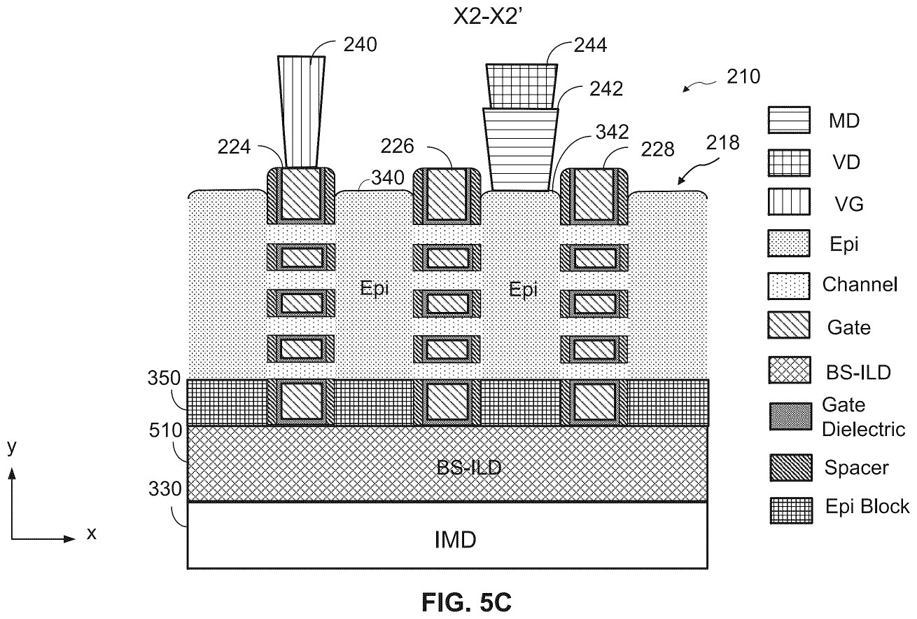

FIG. 5A shows a cross-sectional view of the structure 210 taken along the cross-section line Y-Y′ in FIG. 2, in which the structure 210 is STI free. Making the structure STI free eliminates at least the STI process steps shown in FIGS. 4C to 4F, which reduces process complexity and process costs.

In this example, the first diffusion region 215 includes the first channels 310 passing through the gate 226 and the second diffusion region 218 includes the second channels 315 passing through the gate 226. In the example shown in 5A, the channels 310 and 315 are formed using a gate-all-around FET process in which each of the channels 310 and 315 is surrounded on four sides by the gate 226. However, it is to be appreciated that the present disclosure is not limited to this example.

In this example, the structure 210 includes a continuous backside interlayer dielectric (BS-ILD) 510 extending in the y direction under the first diffusion region 215, the second diffusion region 218, and the gate 226. As used herein, a “continuous” layer is a layer that extends continuously in one or more directions without a break.

In the example shown in FIG. 5A, the BS-ILD 510 extends under the portion of the gate 226 between the diffusion regions 215 and 218 in place of the STI region 325 shown in FIG. 3A. The BS-ILD 510 may include silicon oxide, silicon nitride, silicon carbon oxynitride (SiCON), or another dielectric material. However, it is to be appreciated that the BS-ILD 510 is not limited to these examples, and that the BS-ILD 510 may include other dielectric materials. Since the BS-ILD 510 is electrically non-conductive, the BS-ILD 510 provides isolation between the active devices corresponding to the diffusion regions 215 and 218 without the need for the STI region 325.

In this example, the seams 327 and 328 (i.e., voids) shown in FIG. 3A are not present in the BS-ILD 510. This is because the BS-ILD 510 is formed over a relatively large area after substrate removal, and therefore does not include the seams 327 and 328 caused by back filling narrow trenches with BS-ILD used to form the pillars 320 and 322 in FIG. 3A.

In the example shown in FIG. 5A, the bottom portion of the gate 226 is taller in the z direction than the bottom portion of the gate 226 shown in the example in FIG. 3A. Comparing FIG. 5A with FIG. 3A, the bottom portion of the gate 226 has a height of H2 in FIG. 5A and a height of H1 in FIG. 3A, in which the height H2 is greater than the height H1. In this example, the gate 226 may be made taller to provide a larger margin for substrate (e.g., silicon) removal stop, as discussed further below.

In this example, the BS-ILD 510 is formed on the backside of the chip 100 during backside processing. For example, the diffusion regions 215 and 218, the gate 226, and the topside layers 105 (shown in FIGS. 1A, 1D, and 1E) may be formed during frontside processing. After frontside processing, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off using chemical mechanical polishing (CMP).

In this example, the bottom of the gate 226 may be used as a stop layer to stop the CMP. For example, the CMP for removing the substrate 108 may be performed by a CMP machine that includes a sensor (e.g., an eddy current sensor) configured to sense a change in material during the CMP. A CMP machine may also be referred to as a CMP tool or CMP equipment. In this example, the CMP machine stops the CMP when the sensor detects a change from the substrate material (e.g., silicon) to the gate material (e.g., gate metal). Stopping the CMP when the gate material is detected helps prevent the CMP from going too far and damaging active devices on the chip 100. In this example, making the bottom portion of the gate 226 taller provides a larger margin for stopping the CMP. After the CMP, etching (e.g., plasma etching) may be used to remove the remaining portion of the substrate 108.

It is to be appreciated that the present disclosure is not limited to using the bottom portion of the gate 226 as the CMP stopper. Other structures may also be used as the CMP stopper including, for example, a sacrificial backside contact (BSC) formed during frontside processing, as discussed further below. Another option that may be used for the CMP stopper includes an embedded silicon germanium layer in the substrate. Making the bottom portion of the gate 226 taller also allows the bottom portion of the gate 226 to be used as an etch/clean stopper after the CMP to provide additional process margin, even if the bottom portion of the gate 226 is not needed as a CMP stopper.

FIG. 5B shows a cross-sectional view of the structure 210 taken along the cross-section line X1-X1′ in FIG. 2, which runs in the x direction between the first diffusion region 215 and the second diffusion region 218.

In this example, the BS-ILD 510 extends in the x direction under the gates 224, 226, and 228 and between the first diffusion region 215 and the second diffusion region 218 (shown in FIG. 2). The STI region 325 shown in FIG. 3B is omitted. In this example, the inter-metal dielectric (IMD) 330 is under the BS-ILD 510 instead of the STI region 325 shown in FIG. 3D. As discussed above, the IMD 330 may be used, for example, to isolate structures (e.g., supply rails and ground rails) formed in one or more of the backside metal layers (e.g., backside metal layers 160 in FIGS. 1D and 1E).

FIG. 5C shows a cross-sectional view of the structure 210 taken along the cross-section line X2-X2′ in FIG. 2, which runs in the x direction and intersects the second diffusion region 218. In this example, the second diffusion region 218 includes the first epi layer 340 between the gates 224 and 226 and the second epi layer 342 between the gates 226 and 228. Also, in this example, the epi block layer 350 is disposed below the epi layers 340 and 342 (e.g., to block the epi layers 340 and 342 from growing into the substrate 108 during frontside processing).

In the example in FIG. 5C, the BS-ILD 510 extends in the x direction under the second diffusion region 218. Also, in this example, the gate via 240 is disposed on the gate 224 (e.g., to couple the gate 224 to signal routing in metal layer M0) and the source/drain contact 242 is disposed on the top surface of the second epi layer 342 (e.g., to couple the second epi layer 342 to signal routing in metal layer M0).

The bottom portion of the gate 226 in FIG. 5C is taller in the z direction than the bottom portion of the gate 226 shown in the example in FIG. 3C. As discussed above, the gate 226 may be made taller to provide a larger margin for stopping CMP during backside processing.

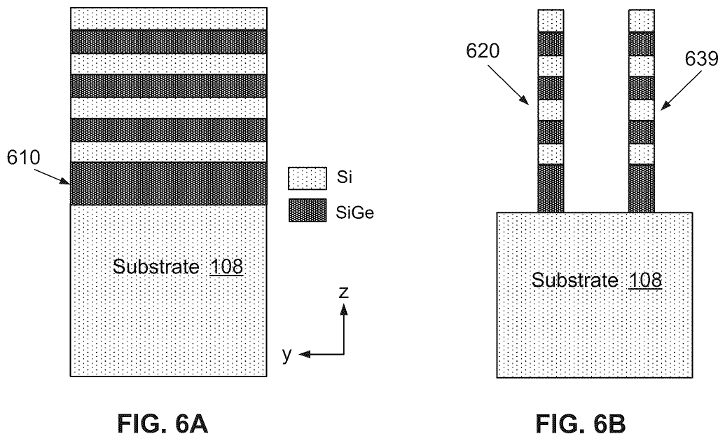

FIG. 6A shows an example of a process for making the bottom portion of the gate 226 taller. In this example, alternating layers of silicon and silicon germanium are deposited on the substrate 108 (e.g., silicon substrate). The layers of silicon are used to form channels (e.g., the channels 310 and 315). The layers of silicon germanium are sacrificial layers that are removed in a later process to form the portions of the gate 226 between the channels. In this example, the bottom silicon germanium layer 610 is made thicker than the other silicon germanium layers. This causes the bottom portion of the gate 226 to be taller when the bottom silicon germanium layer 610 is later removed and replaced with gate material to form the bottom portion of the gate 226.

In FIG. 6B, the alternating layers of silicon and silicon germanium are etched to form the first vertical structure 410 and the second vertical structure 420. In this example, the silicon layers in the first vertical structure 410 may be used to form the first channels 310 and the silicon layers in the second vertical structure 420 may be used to form the second channels 315.

In this example, the STI process steps shown in FIG. 4C to 4F are omitted since the structure 210 in this example does not include the STI. As discussed above, the elimination of the STI process steps reduces process complexity and process cost.

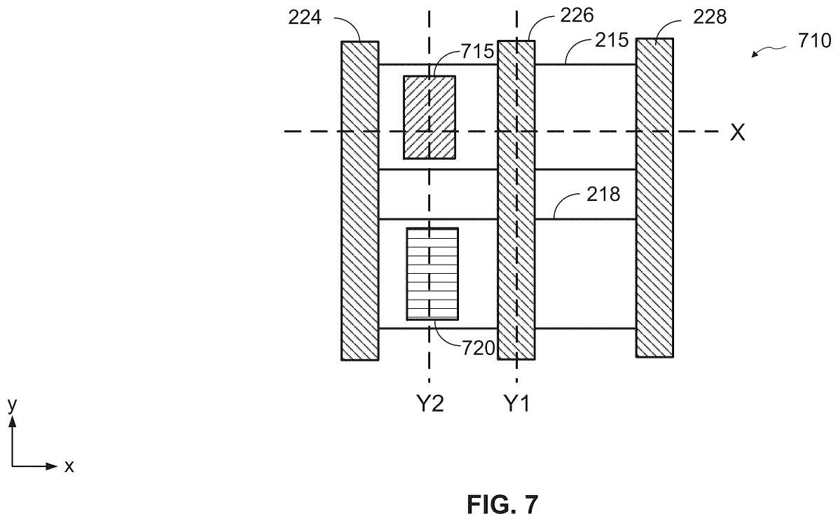

FIG. 7 shows a top view of an exemplary structure 710 on the chip 100 according to certain aspects. In this example, the structure 210 include the first diffusion region 215 and the second diffusion region 218 extending in the x direction. For ease of illustration, the diffusion regions 215 and 218 are shown as rectangles in FIG. 7.

In this example, the structure 710 also includes the gates 224, 226, and 228 extending in the y direction and spaced apart in the x direction. Each of the gates 224, 226, and 228 may include a gate metal (e.g., a high-k metal gate (HKMG)), polysilicon, and/or another gate material. It is to be appreciated that the structure 710 is not limited to the number of gates shown in the example in FIG. 7, and that the structure 710 may include a smaller number of gates or a larger number of gates.

In the example in FIG. 7, the structure 710 includes a backside contact 715 under the first diffusion region 215. As discussed further below, the backside contact 715 may include a sacrificial material that is later removed and replaced with a contact material (e.g., tungsten, cobalt, molybdenum, etc.). As also discussed further below, the backside contact 715 may be used as a stop layer to stop the CMP during backside processing.

In this example, the structure 710 also includes a source/drain contact 720 (e.g., MD contact in FIGS. 1A, 1D, and 1E) disposed on a top surface of the second diffusion region 218. The source/drain contact 720 may couple the second diffusion region 218 to signal routing in metal layer M0.

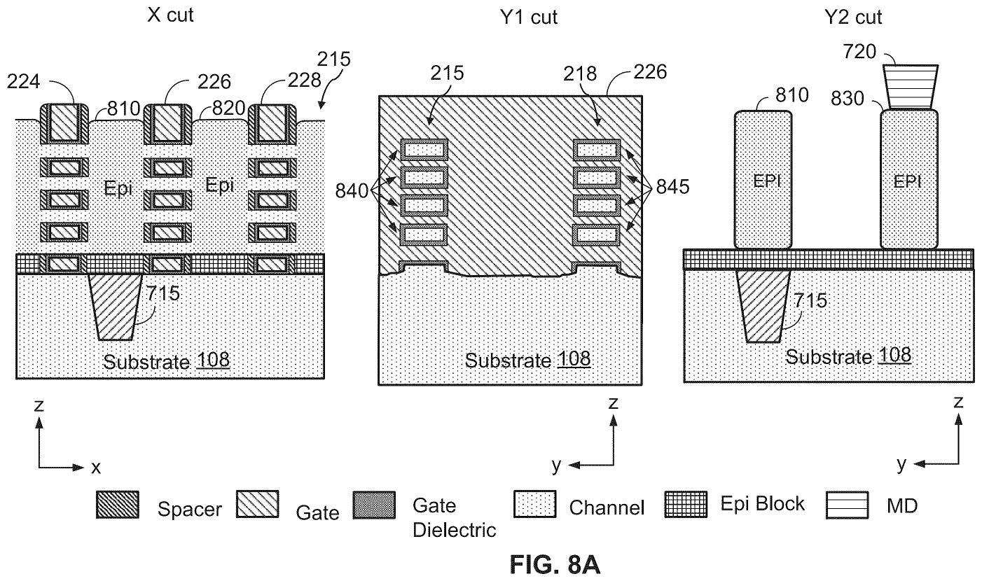

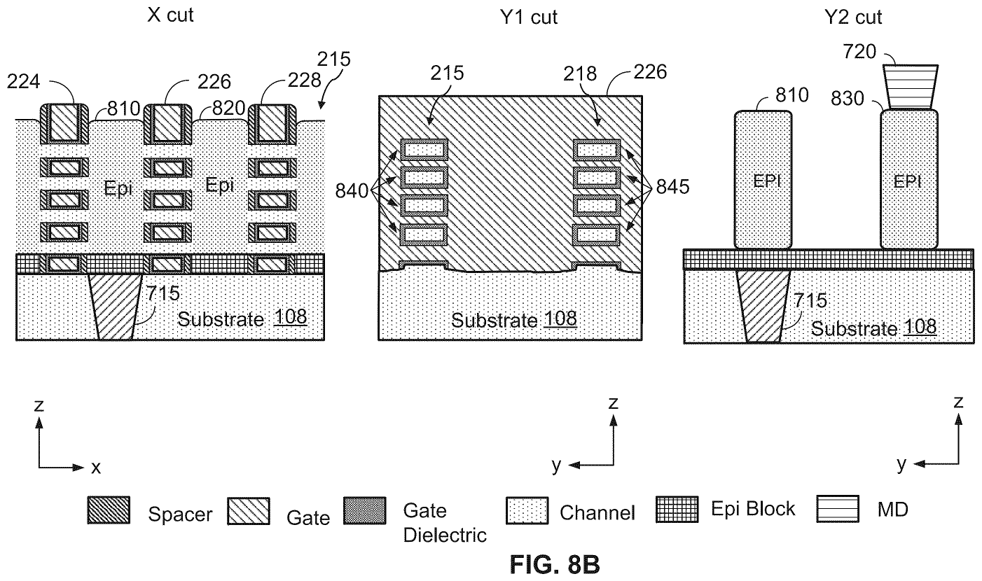

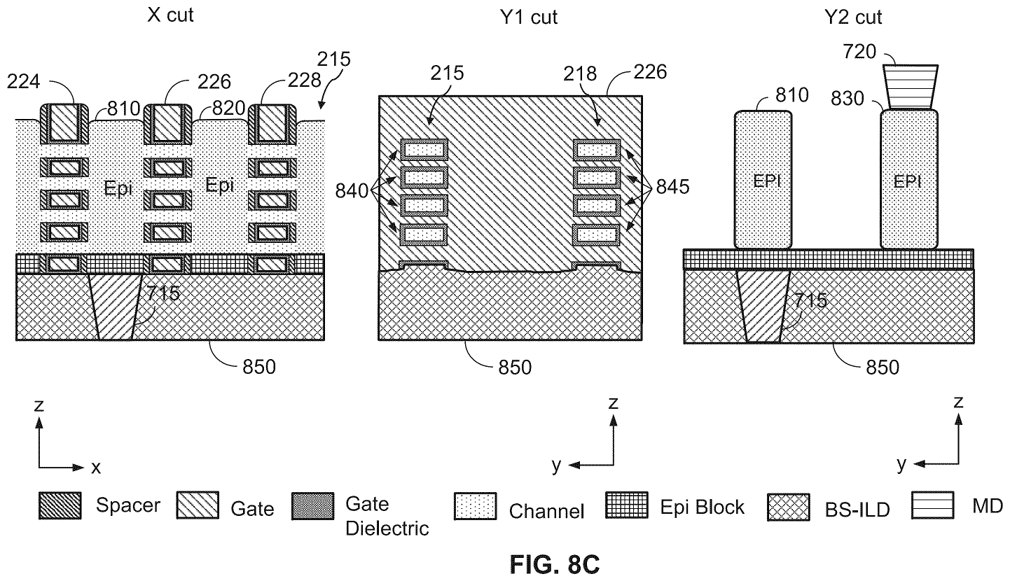

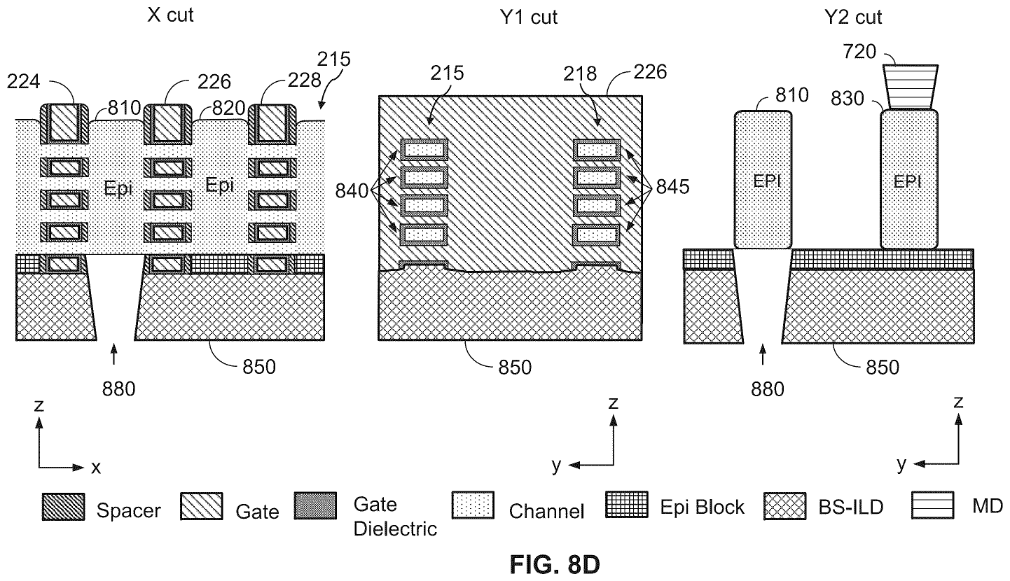

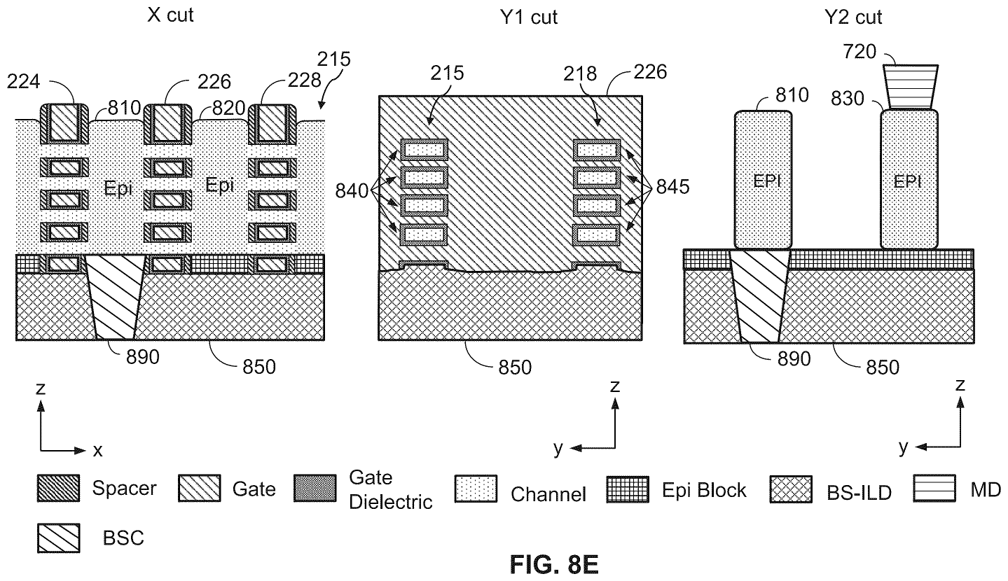

FIGS. 8A to 8C show cross-sectional views of the structure 710 at various stages during processing.

FIG. 8A shows cross-sectional views of the structure 710 taken along the X cut, the Y1 cut, and the Y2 cut in FIG. 7. FIG. 8A shows the structure 710 after frontside processing, in which the diffusion regions 215 and 218, the gates 224, 226, and 228, and the topside layers 105 (shown in FIGS. 1A, 1D, and 1E) are formed on the substrate 108. As shown in FIG. 8A, the structure 710 does not include STI, which eliminates at least the STI process shown in FIGS. 4C to 4F.

As shown in the X cut, the first diffusion region 215 includes a first epi layer 810 between the gates 224 and 226 and a second epi layer 820 between the gates 226 and 228. The second diffusion region 218 also includes a first epi layer 830 (shown in the Y2 cut) between the gates 224 and 226 and a second epi layer (not shown) between the gates 226 and 228. It is to be appreciated that the substrate 108 extends farther down in the z direction than shown in FIG. 8A.

As shown in the Y1 cut, the first diffusion region 215 includes first channels 840 passing through the gate 226, and the second diffusion region 218 includes second channels 845 passing through the gate 226. In the example shown in 8A, the channels 840 and 845 are formed using a gate-all-around FET process in which each of the channels 840 and 845 is surrounded on four sides by the gate 226. However, it is to be appreciated that the present disclosure is not limited to this example.

In this example, the structure 710 also includes the backside contact 715. The backside contact 715 may be formed during frontside process by etching a trench in the substrate 108 (e.g., using a highly directional etching process) and filling the trench with a sacrificial material to form the backside contact 715. Because the backside contact 715 is formed during frontside processing in this example, the backside contact 715 may be used as a stop layer for the CMP, as discussed further below. Note that, in structures with STI, the STI may be used as the stop layer. However, since the structure 710 does not include STI, STI is not available as a stop layer in this example.

FIG. 8A illustrates one example of backside contact integration in which a frontside etch is used to create a backside contact trench (i.e., hole) that is filled with sacrificial material. This is an example of a self-aligned contact flow. However, it is to be appreciated that the present disclosure is not limited to this example for forming the backside contact 715.

FIG. 8B shows the cross-sectional views of the structure 710 in which most of the substrate 108 is removed using CMP. In this example, after frontside processing, a carrier wafer (not shown) is bonded to the top of the chip 100 for structural support. The chip 100 is then flipped to expose the backside of the semiconductor substrate 108, and most or all of the semiconductor substrate 108 is grounded and/or polished off using CMP.

In this example, the backside contact 715 is used as a stop layer to stop the CMP. For example, the CMP machine performing the CMP may include a sensor (e.g., an eddy current sensor) configured to sense a change in material during the CMP. In this example, the CMP machine stops the CMP when the sensor detects a change from the substrate material (e.g., silicon) and the sacrificial material of the backside contact 715.

As shown in FIG. 8B, the portion of the substrate 108 below the backside contact 715 in the z direction is removed by the CMP. The remaining portion of the substrate 108 may have a height approximately equal to the height of the backside contact 715. It is to be appreciated that the present disclosure is not limited to using the backside contact 715 for the stop layer. For example, as discussed above with reference to FIGS. 5A to 5C, the bottom portion of the gate 226 may be used as the stop layer in some implementations. In other implementations, an embedded silicon germanium layer in the substrate 108 may be used as the stop layer.

FIG. 8C shows the cross-sectional views of the structure 710 in which the remaining portion of the substrate 108 is removed and a BS-ILD 850 is formed on the backside of the chip 100. For example, the remaining portion of the substrate 108 may be etched away (e.g., using plasma etching) and the BS-ILD 850 may be deposited on the backside of the chip 100. The BS-ILD 850 may include silicon oxide, silicon nitride, silicon carbon oxynitride (SiCON), or another dielectric material. In certain aspects, the sacrificial material of the backside contact 715 may include a material that is highly selective to silicon to prevent the etching process from removing the backside contact 715. Exemplary materials include silicon nitride (SiN), silicon germanium (SiGe), amorphous carbon, silicon carbide, etc.

As shown in FIG. 8C, the BS-ILD 850 extends in the y under the first diffusion region 215, the second diffusion region 218, and the gate 226. The BS-ILD 850 extends under the portion of the gate 226 between the diffusion regions 215 and 218 in place of the STI region 325 shown in FIG. 3A.

After formation of the BS-ILD 850, the sacrificial material of the backside contact 715 may be removed using an etching process. In this regard, FIG. 8D shows an example in which the sacrificial material is removed, and an epi stop punch through process is performed to remove a portion of the epi top layer under the first epi layer 810. The sacrificial removal process and the epi stop punch through process create a backside trench 880.

In FIG. 8E, the backside trench 880 is filled with contact material to form the backside contact 890 (e.g., BSC in FIGS. 1D and 1E). The contact material may include tungsten, cobalt, molybdenum, ruthenium, etc.

After formation of the backside contact 890, the remaining backside process may be performed including formation of the backside layers (e.g., the backside layers 155 shown in FIGS. 1D and 1E).

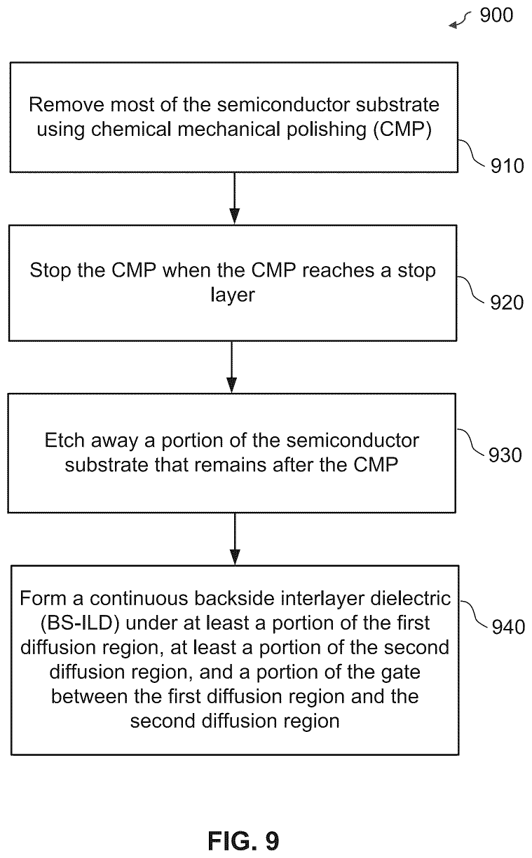

FIG. 9 illustrate a method 900 for processing a chip. The chip includes a first diffusion region (e.g., the first diffusion region 215), a second diffusion region (e.g., the second diffusion region 218), and a gate (e.g., the gate 226) formed on a semiconductor substrate (e.g., the substrate 108).

At block 910, most of the semiconductor substrate is removed using chemical mechanical polishing (CMP). As discussed above, “most” of the semiconductor substrate means at least 90 percent of the semiconductor substrate.

At block 920, the CMP is stopped when the CMP reaches a stop layer. The stop layer may include a bottom portion of the gate (e.g., the gate 226), a backside contact (e.g., the backside contact 715) under the first diffusion region, an embedded silicon germanium layer in the semiconductor substrate, or another stop layer.

At block 930, a portion of the semiconductor substrate that remains after the CMP is etched away. For example, the portion of the semiconductor substrate may be etched away using plasma etching or another type of etching.

At block 940, a continuous backside interlayer dielectric (BS-ILD) is formed under at least a portion of the first diffusion region, at least a portion of the second diffusion region, and a portion of the gate between the first diffusion region and the second diffusion region. The continuous BS-ILD may correspond to the continuous BS-ILD 510 or 850. The continuous BS-ILD may include silicon oxide, silicon nitride, silicon carbon oxynitride (SiCON), or another dielectric material.

Implementation examples are described in the following numbered clauses:

1. A chip, comprising:
a first diffusion region extending in a first direction, the first diffusion region including first channels;
a second diffusion region extending in the first direction, the second diffusion region including second channels;
a first gate extending in a second direction perpendicular to the first direction, wherein the first channels and the second channels pass through the first gate; and
a continuous backside interlayer dielectric (BS-ILD) under at least a portion of the first diffusion region, at least a portion of the second diffusion region, and a portion of the first gate between the first diffusion region and the second diffusion region.

2. The chip of clause 1, wherein the continuous BS-ILD comprises silicon oxide, silicon nitride, or silicon carbon oxynitride (SiCON).

3. The chip of clause 1 or 2, wherein:
the first diffusion region includes a first epitaxial (epi) layer;
the second diffusion region includes a second epi layer;
the chip further comprises a backside contact coupled to a back surface of the first epi layer; and
the continuous BS-ILD extends in the second direction under the second epi layer.

4. The chip of any one of clauses 1 to 3, further comprising a second gate extending in the second direction and spaced apart from the first gate in the first direction.

5. The chip of clause 4, wherein the continuous BS-ILD extends in the first direction under at least a portion of the second gate.

6. The chip of clause 4 or 5, wherein the continuous BS-ILD extends in the first direction under a portion of the second gate between the first diffusion region and the second diffusion region.

7. The chip of any one of clauses 1 to 6, wherein the continuous BS-ILD extends in the second direction under the first channels and the second channels.

8. The chip of clause 7, wherein the continuous BS-ILD extends in the second direction under a portion of the first gate between the first channels and the second channels.

9. A chip, comprising:
a first diffusion region extending in a first direction, the first diffusion region including first channels;
a second diffusion region extending in the first direction, the second diffusion region including second channels;
a first gate extending in a second direction perpendicular to the first direction, wherein the first channels and the second channels pass through the first gate; and
a continuous backside interlayer dielectric (BS-ILD) under the first channels, the second channels, and a portion of the first gate between the first channels and the second channels.

10. The chip of clause 9, wherein the continuous BS-ILD comprises silicon oxide, silicon nitride, or silicon carbon oxynitride (SiCON).

11. The chip of clause 9 or 10, wherein:
the first diffusion region includes a first epitaxial (epi) layer;
the second diffusion region includes a second epi layer;
the chip further comprises a backside contact coupled to a back surface of the first epi layer; and
the continuous BS-ILD extends in the second direction under the second epi layer.

12. The chip of any one of clauses 9 to 11, further comprising a second gate extending in the second direction and spaced apart from the first gate in the first direction, wherein the continuous BS-ILD extends under a portion of the second gate between the first diffusion region and the second diffusion region.

13. The chip of clause 12, wherein the continuous BS-ILD extends in the first direction under a portion of the second diffusion region between the first gate and the second gate.

14. A method for processing a chip, wherein the chip includes a first diffusion region, a second diffusion region, and a gate formed on a semiconductor substrate, the method comprising:
removing most of the semiconductor substrate using chemical mechanical polishing (CMP);
stopping the CMP when the CMP reaches a stop layer;
etching away a portion of the semiconductor substrate that remains after the CMP; and
forming a continuous backside interlayer dielectric (BS-ILD) under at least a portion of the first diffusion region, at least a portion of the second diffusion region, and a portion of the gate between the first diffusion region and the second diffusion region.

15. The method of clause 14, wherein the stop layer comprises a bottom portion of the gate.

16. The method of clause 14, wherein the stop layer comprises a backside contact under the first diffusion region.

17. The method of clause 14, wherein the stop layer comprises an embedded silicon germanium layer in the semiconductor substrate.

18. The method of any one of clauses 14 to 17, wherein the semiconductor substrate comprises silicon.

19. The method of any one of clauses 14 to 18, wherein the continuous BS-ILD comprises silicon oxide, silicon nitride, or silicon carbon oxynitride (SiCON).

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first diffusion region extending in a first direction, the first diffusion region including first channels;
a second diffusion region extending in the first direction, the second diffusion region including second channels;
a first gate extending in a second direction perpendicular to the first direction, wherein the first channels and the second channels pass through the first gate; and
a continuous backside interlayer dielectric (BS-ILD) under at least a portion of the first diffusion region, at least a portion of the second diffusion region, and a portion of the first gate between the first diffusion region and the second diffusion region.

2. The chip of claim 1, wherein the continuous BS-ILD comprises silicon oxide, silicon nitride, or silicon carbon oxynitride (SiCON).

3. The chip of claim 1, wherein:
the first diffusion region includes a first epitaxial (epi) layer;
the second diffusion region includes a second epi layer;
the chip further comprises a backside contact coupled to a back surface of the first epi layer; and
the continuous BS-ILD extends in the second direction under the second epi layer.

4. The chip of claim 1, further comprising a second gate extending in the second direction and spaced apart from the first gate in the first direction.

5. The chip of claim 4, wherein the continuous BS-ILD extends in the first direction under at least a portion of the second gate.

6. The chip of claim 4, wherein the continuous BS-ILD extends in the first direction under a portion of the second gate between the first diffusion region and the second diffusion region.

7. The chip of claim 1, wherein the continuous BS-ILD extends in the second direction under the first channels and the second channels.

8. The chip of claim 7, wherein the continuous BS-ILD extends in the second direction under a portion of the first gate between the first channels and the second channels.

9. A chip, comprising:
a first diffusion region extending in a first direction, the first diffusion region including first channels;
a second diffusion region extending in the first direction, the second diffusion region including second channels;
a first gate extending in a second direction perpendicular to the first direction, wherein the first channels and the second channels pass through the first gate; and
a continuous backside interlayer dielectric (BS-ILD) under the first channels, the second channels, and a portion of the first gate between the first channels and the second channels.

10. The chip of claim 9, wherein the continuous BS-ILD comprises silicon oxide, silicon nitride, or silicon carbon oxynitride (SiCON).

11. The chip of claim 9, wherein:
the first diffusion region includes a first epitaxial (epi) layer;
the second diffusion region includes a second epi layer;
the chip further comprises a backside contact coupled to a back surface of the first epi layer; and
the continuous BS-ILD extends in the second direction under the second epi layer.

12. The chip of claim 9, further comprising a second gate extending in the second direction and spaced apart from the first gate in the first direction, wherein the continuous BS-ILD extends under a portion of the second gate between the first diffusion region and the second diffusion region.

13. The chip of claim 12, wherein the continuous BS-ILD extends in the first direction under a portion of the second diffusion region between the first gate and the second gate.

14. A method for processing a chip, wherein the chip includes a first diffusion region, a second diffusion region, and a gate formed on a semiconductor substrate, the method comprising:
removing most of the semiconductor substrate using chemical mechanical polishing (CMP);
stopping the CMP when the CMP reaches a stop layer;
etching away a portion of the semiconductor substrate that remains after the CMP; and
forming a continuous backside interlayer dielectric (BS-ILD) under at least a portion of the first diffusion region, at least a portion of the second diffusion region, and a portion of the gate between the first diffusion region and the second diffusion region.

15. The method of claim 14, wherein the stop layer comprises a bottom portion of the gate.

16. The method of claim 14, wherein the stop layer comprises a backside contact under the first diffusion region.

17. The method of claim 14, wherein the stop layer comprises an embedded silicon germanium layer in the semiconductor substrate.

18. The method of claim 14, wherein the semiconductor substrate comprises silicon.

19. The method of claim 14, wherein the continuous BS-ILD comprises silicon oxide, silicon nitride, or silicon carbon oxynitride (SiCON).
